(19) United States
(12) Patent Application Publication
(10) Pub. No.: US 2005/0226079 A1
(43) Pub. Date: Oct. 13, 2005

(54) Methods and apparatus for dual port memory devices having hidden refresh and double bandwidth

(76) Inventors: Yiming Zhu, Belmont, CA (US); Qingming Shu, Milpitas, CA (US)

Correspondence Address: EMIL CHANG;LAW OFFICES OF EMIL CHANG, 874 JASMINE DRIVE, SUNNYDALE, CA, 94086, US

(21) Appl. No.: 10/928,504

(22) Filed: Aug. 26, 2004

Related U.S. Application Data
(60) Provisional application No. 60/561,119, filed on Apr. 8, 2004.

(51) Int. Cl. G11C 7/00

(52) U.S. Cl. 365/230.03

(57) ABSTRACT

Memory methods and apparatuses providing for refresh and bandwidth enhancements for a dual-port memory array (e.g. a DRAM memory array) with balanced read and write timing specifications are disclosed. A port allocation for dual-port memory cell is adopted such that one port is assigned and shared for both read and refresh and the other port is assigned for write only. Double bandwidth is achieved by overlapping simultaneous read or refresh and write port access during the same cycle. No external refresh command is required and external accesses (reads and writes) are not interrupted or delayed under any circumstance. A high-speed SRAM compatible device can be fabricated from a dual-port DRAM or 3-Transistor cells or 2-Transistors and 1 capacitor cells. The preferred embodiments include a multi-bank dual-port memory array and a look-up-table logic which records the accessed word address and generates hit logic and idle cycles when a refresh stall is asserted by a refresh-jammed bank. A dual-port memory data lodge which temporarily detours the data flow is provided to store the data flow and to allow for refresh to occur in the refresh-jammed bank. Each of dual-port DRAM banks has its independent read, write and refresh decoder control. Therefore, simultaneous refresh and read-write operations are allowed in different banks. The size of data lodge is determined by guaranteeing that the refresh operations can be executed without pausing ongoing indefinite read and write operations.

### CLAIM OF PRIORITY

This application claims priority from a provisional patent application entitled “Method and Apparatus of Hidden Refresh and Double Bandwidth of a Dual Port Semiconductor Memory” filed on Apr. 8, 2004, having a Provisional Patent Application No. 60/561,119. These applications are incorporated herein by reference.

### FIELD OF INVENTION

The present invention relates to memory devices, and in particular to DRAM memory devices and SRAM compatible memory devices.

### BACKGROUND

High performance network equipments, such as routers and switches, demand superior bandwidth and throughput of SRAM. The new type of high performance memory with balanced read and write timing specification, for examples QDR II and Sigma SRAM, supports both read and write transactions simultaneously. In the prior art, memory cells must be accessed twice in one cycle via a single port and memory access has to be serialized. The constraint of single-port memory cell limits the achievable performance of this architecture.

The conventional SRAM cell is composed of 6-transistor or 4-transistor and 2-resistors. Therefore, a conventional DRAM cell with one transistor and one capacitor is significantly smaller and a dual-port DRAM cell with two transistors and one capacitor is still much smaller. Yet, charge leakage in DRAM cells need be compensated periodically by a refresh operation, while SRAM cells can hold their values indefinitely as long as power is supplied. The issue with refresh operations is that these operations require memory access time and thereby attenuates the throughput of a memory system.

Previous attempts to use DRAM cells in SRAM applications have been of limited success for various reasons. For example, one such DRAM device has required an external signal to control refresh operations. Moreover, external access to this DRAM device is delayed during memory refresh operations. Consequently, the refresh operations are not transparent and the corresponding DRAM device is not fully compatible with a SRAM device. Furthermore, the memory read and write cycle for a SRAM cell is faster than a DRAM cell on a similar architecture and process generation. It also limits the DRAM cell from being used in high-speed applications, such as for routers and switches.

In another prior art scheme, a high-speed SRAM cache is inserted between a slower DRAM array and a SRAM interface in order to speed-up the average access time and the bandwidth throughput (see U.S. Pat. No. 5,559,7520 by Katsumi Dosaka et al, and Data Sheet of 16 Mbit Enhanced Memory Systems Inc., 1997). The real access time is depended upon the cache hit or miss and the cache hit rate determines the actual bandwidth and throughput. However, the cache dependency disqualifies this device for predictable random access time mandated by the SRAM specification.

Another prior art scheme (U.S. Pat. No. 5,999,474), a complete hiding of the refresh of a semiconductor memory is proposed. A write-back and direct map cache scheme is adopted to allow refresh operations to be purely transparent to external accesses. However, both cache tag memory access and comparison logic generation seriously degrade the read random access time. Moreover, it is very challenging to design a super fast (at least doubling the speed of a DRAM bank) cache tag memory and a SRAM cache with the same capacity but much larger geometry of a DRAM bank. If such a device is designed to match the speed of a high-performance SRAM device, such design of a cache tag for a SRAM cache memory will be prohibitive and its size and speed are dependent on the address bits width at large. For example, a read operation is required from an external device and, first, it must access the content of the cache tag memory which requires at least half a cycle and then the retrieved content is compare with the current address (further delay the access time); if a read miss is found, this read operation will then go to a real DRAM bank to load the data out. Therefore, a read operation is delayed by more than half a cycle. Also, this prior art doesn't leverage the nature of dual-port memory to enhance refresh hiding. As a result, serious degradation of random access time and hard-designed cache tag and cache memory prevent this device from becoming the replacement of high-performance SRAM though it is functionally compatible.

Accordingly, it would be desirable to have a memory device that utilizes area-efficient DRAM cells and dual-port technology to double the bandwidth of a memory system, and handles the refresh of the dual-port DRAM cells in a way which is totally transparent to an external client device. Moreover, this refresh mechanism should not require any faster and hard-designed cache memory and should have minimal impact on random access time of the memory device. That is, it would be desirable to have a memory device that allows the use of DRAM cells or other refreshable memory cells for building ultra high-performance SRAM compatible memory devices.

### SUMMARY OF INVENTION

An object of the present invention is to provide DRAM memory devices that are compatible with SRAM memory devices.

Another object of the present invention is to provide dual-port memory devices having refresh operations transparent to external devices.

Yet another object of the present invention is to provide dual-port memory devices having a first port handling write operations and a second port handling read and refresh operations.

Briefly, a memory device, comprising an address latch for receiving one or more data addresses; an input buffer for receiving data to be written to said memory device; access logic for receiving one or more request signals indicating a read operation or a write operation to said memory device; one or more memory banks, each of said memory banks having a plurality of dual-port memory cells, wherein each of said memory cells having a first port designated for write operations only and a second port designated for read and refresh operations only, and said memory cells requiring refresh operations on a periodic basis; a control circuit for operating said memory banks in response to said request signals and for coordinating the refreshing of said memory cells without delaying any read operations or write operations, is disclosed.

An advantage of the present invention is that it provides DRAM memory devices that are compatible with SRAM memory devices.

Another advantage of the present invention is that it provides dual-port memory devices having refresh operations transparent to external devices.

Yet advantage of the present invention is that it provides dual-port memory devices having a first port handling write operations and a second port handling read and refresh operations.

### BRIEF DESCRIPTION OF DRAWINGS

FIG. 1 shows a block diagram of a 3-T FPSRAM memory device with balanced read and write operations in accordance with the preferred embodiment of the present invention.

FIG. 2a shows a schematic diagram of a dual-port memory cell used in memory banks disclosed in the preferred embodiment of the present invention.

FIG. 2b shows a schematic diagram of a dual-port memory cell used in the memory data lodge disclosed in the preferred embodiment of the present invention.

FIG. 3 shows a schematic diagram of a LUT entry cell in accordance with the preferred embodiment of the present invention.

FIG. 4 shows a block diagram of the LUT logic system with LUT entry cells in accordance to the preferred embodiment of the present invention.

FIG. 5 shows a schematic diagram of a hit logic generator implemented in LUT logic in accordance to the preferred embodiment of the present invention.

FIG. 6 shows a block diagram of a memory data lodge system in accordance with the preferred embodiment of the present invention.

FIG. 7 shows a waveform diagram illustrating the overlapping read or refresh and write operations executed sequentially in accordance with the preferred embodiment of the present invention.

FIG. 8 shows a waveform diagram illustrating the timing of hit generation in four consecutive read operations in accordance with the preferred embodiment of the present invention.

FIG. 9 shows a waveform diagram illustrating the timing of hit generation in four consecutive read and write operations in accordance with the preferred embodiment of the present invention.

FIG. 10 shows a waveform diagram illustrating the timing of four consecutive read and write operations in accordance with the preferred embodiment of the present invention.

### DETAILED DESCRIPTION

The present invention is related to semiconductor memories, such as dynamic random access memory (“DRAM”) and static random access memory (“SRAM”); however, it shall be understood that it is not to be limited to such kind of memory devices. In particular, the present invention relates to methods and apparatuses for completely hiding the refresh operations (or being transparent to external devices) and boosting the bandwidth of a semiconductor memory so that the refresh operations do not affect external access read or write operations. Moreover, overlapping read and write operations are allowed for the same memory cell.

In the presently preferred embodiment, the memory cells include a first port and a second port. The first port is assigned for both read and refresh operations while the second port is associated with write operations only. Here, port allocation is an important key to simplify the complicated refresh mechanism, and to eliminate the speed requirement for the data lodge (where the data lodge can have the same specification as the memory banks). It also allows the implementation of a simple write-through policy strategy in a dual-port memory data lodge. Since no refresh activity is assigned to the write port, data path and control related to the write transaction is easily designed like the write transaction for a regular SRAM or DRAM without consideration for the refresh operation. However, the read port needs to perform refresh operations during idle cycles.

However, note that a read operation itself in a DRAM is a cascade operation with a refresh operation plus a data transfer out operation. Thus, the control circuitry is less burdensome to implement. The read data path does not involve the refresh operation and thus it has a similar degree of design effort as a regular one. More importantly, the read operation is a data coherent process since no data is modified during this process. Given a finite configuration of memory banks, there is a definite time period to register all the data in the bank before an idle cycle can be created for a waiting refresh request. Therefore, the refresh operation associated with the read port is highly preferred and straightforward.

In the preferred embodiment, the memory device is operated by a separated external read and write data bus and a control signal but shares an address bus. Therefore, the memory device has the capability to operate read operations and write operations starting from the different edges of a cycle. In the preferred embodiment, the read and write operations are composed of a cell access phase and a channel transfer and acquisition phase. Refresh operations are composed of a cell access phase and a channel acquisition phase. The read and write operations can be overlapped thru non-overlapping cell access phase or pipelined to use a shared cell storage node. Therefore, double-bandwidth is achieved by overlapping read operations and write operations in dual-port cells with a fixed port allocation.

In accordance with the present invention, the presently preferred embodiment is a high-speed SRAM compatible device with balanced read and write timing specification implemented using 3-transistor or dual-port memory cells (e.g. as DRAM memory cells). This SRAM compatible device can be referred to as a three-transistor fast pseudo SRAM (3-T FPSRAM).

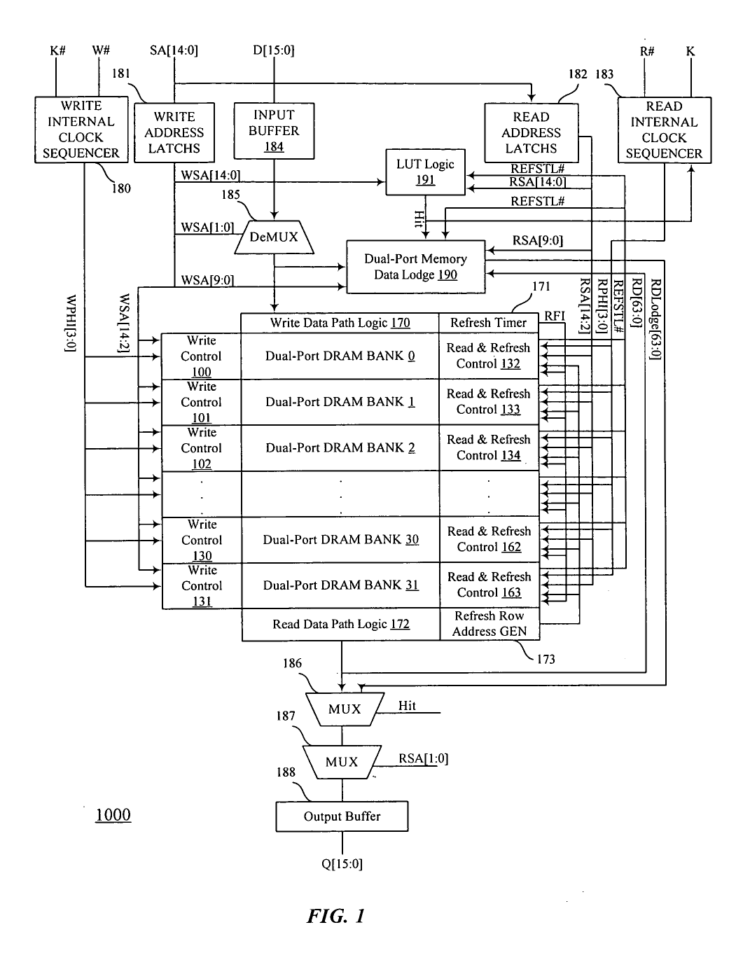

FIG. 1 shows a block diagram of a presently preferred embodiment memory device 1000 having balanced read and write operations in accordance with the present invention. Note that the present invention can be implemented in a wide variety of manners and is not limited to the preferred embodiment and alternate embodiments described below. Furthermore, it is applicable to other types of memory devices and memory architectures.

Here, the preferred embodiment is illustrated with an example having 32 dual-port memory banks 0-31, 32 write control circuitries 100-131, and 32 read and refresh control circuitries 132-163. Write control circuits 100-131 are coupled to receive the write address and controls signals related to the write transactions to the respective dual-port banks 0-31. Read and refresh control circuits 132-163 are coupled to receive the read address, refresh address and controls signals related to the read and refresh transactions to the respective dual-port banks 0-31. Each bank has a capacity of 1024 words, each word having a length of 16-bits.

Each of dual-port memory banks 0-31 includes an array of 32 rows and 512 columns of dual-port memory cells. The 32 dual-port memory banks 0-31 have a shared read bus attached to a common read data path logic 172, and a shared write bus attached to a common write data path logic 170. Refresh timer 171 generates and broadcasts the refresh invoke command to all dual-port memory banks 0-31. Refresh row address generator 173 produces the refresh row address one by one to serve the refreshing of the whole banks 0-31 completely.

The memory device 1000 also includes a write internal clock sequencer 180, a write address latches 181, read address latches 182, read internal clock sequencer 183, input buffer 184, demux 185, mux 186, mux 187, output buffer 188, dual-port memory data lodge 190, and LUT logic 191. These blocks in general control the accesses of the memory device 1000 and are described in further details below.

The memory device 1000 receives the following external signals: input address SA[14:0], clock signal pairs K and K#, write enable signal W#, read enable signal R#, input data signals D[15:0] and output data signals Q[15:0]. The clock signal pairs K and K# are provided for synchronous memory access. The symbol “#” denote active low signal. Note that the external signals listed above do not include any signals relating to refresh activities for the dual-port memory banks 0-31.

SA[14:0] has 15 bits which is divided into 4 fields. Address bits SA[14:10] represents a 5-bit bank address which identifies 32 dual-port memory banks 0-31. Address bits SA[9:5] represents a 5-bit row address which identifies 32 rows in each dual-port memory bank. Address bits SA[4:2] represents a column address that identifies one of the 8-bits in the 512 columns of each memory bank. Address bits SA[1:0] represents a nibble address field which identifies one of four 16-bit words from the 64 bit internal data bus.

The external read access is initiated to the memory device 1000 by asserting a logic low read enable signal R#, and providing a memory address SA[14:0]. The memory device 1000 samples the R# signal and SA[14:0] thru read address latches 182 at the positive or rising edge of clock K and recognizes the read request.

In a read operation, in the case where the memory bank to be read from has issued a refresh stalled signal, the LUT logic 191 is checked first to determine whether the data of the targeted memory cell as been previously stored in the memory data lodge 190. If the LUT logic determines that the data is available in the memory data lodge 190, a hit is issued to trigger the necessary pathway to output the data from the memory data lodge 190, thus relieving the targeted memory bank from being accessed and allowing a refresh operation to be done for such memory bank. If the LUT logic 191 determines that there is not a hit, then the data is read from the memory cell corresponding to the given address but also the read data is stored in the memory data lodge 190 and the corresponding entry in the look-up table in the LUT logic 191 is marked as being current. In this manner, upon a refresh-stall signal, data in the refresh-jammed memory bank is transferred to the memory data lodge and when data is being read again from a previously accessed memory cell of the refresh-jammed bank, the memory data lodge can provide the requested data and thereby allowing the refresh-jammed bank to refresh.

The external write access is initiated to the memory device 1000 by asserting a logic low write enable signal W#, and providing a memory address SA[14:0]. The memory device 1000 samples W# signal at the positive edge or rising edge of clock K and SA[14:0] thru write address latches 181 at the positive or rising edge of clock K# and recognizes the write request.

In a write operation, in the preferred embodiment, when the refresh-stalled signal is active with respect to memory cells of a memory bank, a write-through policy is utilized where data is written to both the targeted memory cell as well as the corresponding location for such memory cell in the memory data lodge 190.

Output data for read transaction is sent out from output buffer 188 starting from the next rising edge after read enable logic is asserted low. Input data for write transaction is registered into input buffer 184 at the rising edge of clock K after write enable logic is asserted low. Since there are separate read and write control circuits and allocation of the dual ports, there is no intervention between the read and write transactions.

In the preferred embodiment, the memory cells are arranged in a plurality of independently controlled memory banks. Thus, each bank can execute refresh operations simultaneously and independently. A read operation and a write operation can take place in the same bank concurrently. All of the memory banks in a block are connected to a read bus with a read data path, so that data read from any one of the banks is sent to the read data path. All of the memory banks in a block are further connected to a write bus with a write data path, so that the data written to any one of the memory banks is received from the write data path. In the preferred embodiment, one read operation and one write operation can take place in a block in a cycle because of a shared read bus and a shared write bus. Depending on the particular bus architecture or the bus schedule, more than one read operations and write operations can take place.

The refresh operation can be simultaneously executed for the different banks. The control of the read operations and write operations for each bank is allocated to different ports but the number of read and write operations in the different banks are limited by the read and write bus capability. In the preferred embodiment, one read and one write transaction can be executed in one of the memory banks during any one cycle. The dual-port memory bank allows simultaneous read and write operation in the same bank in one cycle via overlapping read and write operation in the described embodiment of the present invention. However, it is to be noted that the present invention is not limited to one read operation and one write operation in a given cycle. Depending on the bus architecture and the bus schedule, more than one read operation and write operation can take place.

A refresh invoke command is broadcasted to all the banks so that if no bank read operation is pending, the memory banks receiving the refresh broadcast will run through a refresh cycle to retain the data value. A refresh address is generated by a global refresh counter, and the local refresh-and-read access control of the respective memory bank multiplex such address in order to select the memory cells to refresh.

A memory data lodge 190 and a LUT logic 191 is introduced to temporarily store data and register address only if a refresh request is generated by a refresh-jammed bank, meaning that a particular bank is unable to refresh due to continuous read and/or write operations. The size of the memory data lodge 190 is selected to be the same as the configuration of a memory bank. Even in the worst scenario, this configuration will guarantee that all refresh operations of the memory banks are executed within a predetermined refresh period. In the example of the preferred embodiment, the size of LUT logic entries is selected to store 1024 bits, which corresponds 1024 words in each memory bank.

As described above, the control circuitry includes a LUT logic 191 and a dual-port memory date lodge 190, which can have the same configuration, memory cell and speed grade as each of the memory banks. The output of the memory data lodge 190 is connected to a read data path (via mux 186); and the input of the memory data lodge 190 is connected to a write data path (via mux 185). These connections allow the transfer of data from the memory banks to the memory data lodge 190. The read and write data path of the memory data lodge 190 is further coupled to the external data in bus (via demux 185) and data out bus (via demux 186). The memory data lodge 190 is used to temporarily detour the data flow when there is a refresh request not being fulfilled for a memory bank. The memory data lodge 190 is used until such a detour creates a successful idle cycle for the bank demanding the refresh.

The memory data lodge 190 implements a write-through policy, such that all write data are written to the memory data lodge 190 and its destination memory bank in the same cycle. In the preferred embodiment, the LUT logic 191 includes a look-up table and its relevant logic. Each entry of the look-up table is a bit that represents whether data of a specified address in a refresh-jammed bank is registered in the memory data lodge 190. The hit logic is generated very quickly from the input address because of a ready or settled value of bit entry in the look-up table.

The LUT logic 191 is activated and carried out as follows. First, a refresh timer issues a refresh command to all the banks. If a bank is currently in read status, the refresh command is held on until an idle cycle takes place. There is a programmable counter or logic to determine when to generate a refresh request to the LUT logic after a refresh command is stalled continuously in a bank. For example, if a refresh command is hold up for 4 memory cycles without an idle cycle, a refresh stall (REFSTL#) will be issued to activate the LUT logic 191. Otherwise, both the LUT logic 191 and the memory data lodge 190 are disabled and will not participate in any memory activity. Note that the initial values for all entries in the LUT logic are preset to “1”. When a refresh stall is set up and the read command is continuously issued to the refresh-jammed bank, the LUT logic 191 starts to register the read address into the look-up table entry. Since the output word has a certain width, for example, 16 bits wide, the total number of the entries for a memory bank with 32 rows and 512 columns is 1024. It can be grouped into 32 rows and 32 columns as a small piece of array with a LUT cell. The read address is composed of 5 bit for row address and 5 bit for column address and the rest are for the bank addresses.

A row and column decoder is required to decode the 5-bit input and to locate the entry in the look up table. Thus, value in this entry is set to 0 which indicates that this address has been accessed. The data read out from the refresh-jammed bank will be written into the memory data lodge 190 in order to detour the future access to the same address. Original value in all entries is 1 by default so that the hit logic yields 0. Note that the bank address portion need not be handled in the LUT logic for the read operation, simply because as long as the refresh request is hold, read access must be in this particular refresh-jammed bank; otherwise, an idle cycle in this bank is automatically generated by the switch of read bank address and both the LUT logic and the memory data lodge are disabled thereafter. Therefore, there is no need for extra logic to judge the bank address in the LUT logic 191 and this saves random access time. If a registered read address takes place again, the decoder will turn on the evaluate logic and a hit logic will be set as 1 very quickly since its entry content has turned on its switch after its initial write-in and there are no extra timing need to read this entry.

After a hit logic is detected, the memory data lodge will decode the read address and send the corresponding data to external data bus (via mux 186) and an idle cycle is created for refresh-jammed memory bank. Thus, a stalled refresh command can be carried out in this cycle immediately. In the worst scenario, all the 1024 entries in the LUT logic are accessed and set before a hit happens. It implies that the predetermined refresh period to hold a data valid in memory cell has to be larger than 32 times of 1024 clock cycles plus the cycles to turn on the refresh request signal, if the worst scenario above takes place in all 32 word lines in this given example.

If there are write operations which modify the content of the memory banks, particularly, registered content of the memory data lodge 190, the LUT logic 191 and memory data lodge 190 will collaborate to carry out a write-through policy as follows. Note that only when refresh stall is on, write operations in the refresh-jammed bank need to be tendered. Bank address need to be compared and done in this case before a write to the LUT logic 191 and the memory data lodge 190. However, it does not affect random access time for the read operation. The LUT logic decodes the write address and sets the related entry as 0 thru a second write port which indicates the entry is modified and registered. The corresponding entry in the memory data lodge 190 will be written and updated by the data from the external data bus thru its second write port; and the designated memory bank is also written with the same data from the external data bus in the same cycle. Under this policy, data coherency and integrity is kept. Thereby, any data written into a refresh-jammed bank will be redirected and written into the memory data lodge 190 and the corresponding entry in the LUT logic is set. If any read address hits registered entry whatever is from either previous read or write operation, a hit signal will be generated as described above and an idle cycle is created for the refresh-jammed memory bank.

Note that the memory data lodge 190 has two ports with a port allocation policy different from the memory banks, although its memory cell structure can be the same. That is, one port is a read and write port and the second port is a write port. Simply, the memory data lodge 190 does not need to be refreshed, because any refresh stall can be resolved within the worst scenario time period of 1024 cycles which is much smaller than the predetermined refresh period. The read operation in the memory data lodge happens only when a hit is triggered; otherwise, the ports are kept as write ports for the redirected read data from the respective memory bank. After the hit cycle, the refresh request will be disabled and all the entries in the LUT logic 191 will be reset and the data in the memory data lodge 190 will not matter.

Note that redirected data for registered read to the memory data lodge 190 is delayed for one cycle. This raises a data coherency problem. However, it only happens in the same address read and write sequence in one cycle since the different address read and write is uncorrelated and in more than one cycle there is no data integrity problem for only one cycle delay. A data forwarding mechanism is used in the memory data lodge 190. Since the data for write sequence is still valid before a redirected data is written, a mux is used in data path to forward the most updated data.

In the preferred embodiment, any read and write operation in the memory data lodge 190 and any of the memory banks can be executed in an overlapping mode. Any memory access is divided into a cell access phase and a channel transfer and acquisition phase. In the cell access phase, the access port is turned on, and the cell is exposed to the external channel for either reading or writing. In the channel transfer phase, data read from and write to a cell is from or to external or internal data bus. In the channel acquisition phase, the channel is pre-charged and prepared to a certain electrical status before moving to the next phase. A dual-port cell allows two separated channels without intervention between the two channels. Cell accesses from the two channels can be executed serially without wasting any bandwidth to the cell. If the cell access phase is less than or equal to half of whole memory access cycle, total overlapping or double-bandwidth could be achieved in such a manner.

The memory data lodge 190 having the same speed grade as any of the memory banks can detour data flow in the overlapping mode. Any of the memory banks can also operate in double-bandwidth speed while in overlapping mode. The LUT logic 191 has two write ports for entry bit setup to be overlapped in same manner. In the preferred embodiment, the overlapping mode is allowed by the external timing specification. From the external data bus, the read address is issued at positive edge of clock K and the write address is issued at negative edge of clock K or positive edge of reverse phase clock K#. Both the write and read commands (W# and R#) can be issued at the positive edge of clock K. A separated data in and out bus can be utilized to further quadruple data throughput or a shared data bus can be designed to operate data in double bandwidth. In an alternate embodiment, burst mode and data valid window in half cycle in separated data input and output bus achieves quadruple data rate in the present scheme. In yet another embodiment, the shared data bus is implemented by latching input data at rising edge of clock K and sending output data at falling edge of clock K# with data valid window of half cycle.

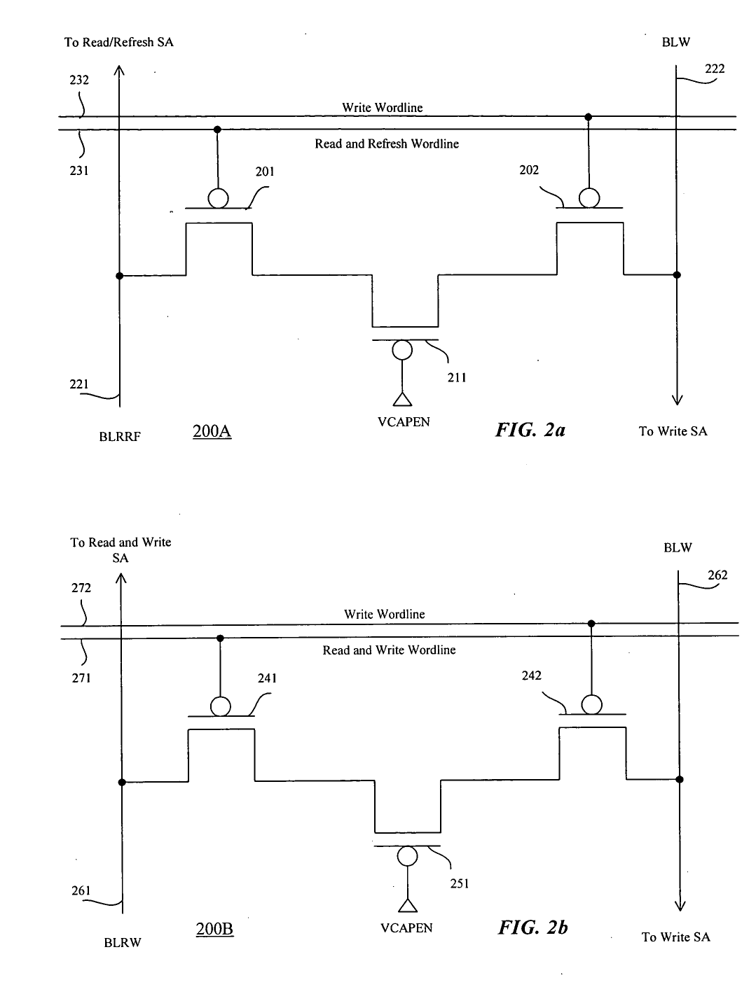

FIG. 2a shows a schematic diagram of dual-port DRAM cell 200A that may be used in the memory banks of the embodiments disclosed herein. Here the dual-port DRAM cell 200A has two ports 201 and 202. Port 201 is controlled by the read and refresh wordline 231 and port 202 is controlled by the write wordline 232. The dual-port DRAM cell 200A includes a storage node 211, which may be a PMOS capacitor. The active channel of PMOS capacitor 211 is the place to store data charge. In order to keep channel active in data “0” scenario, external voltage VCAPEN is hold as a negative voltage generated by charge pump or from an external source. Port 201 is turned on only when either read or refresh activity takes place for the cell and port 202 is turned on only when write activity takes place for the cell. After port 201 is on, the voltage held in storage cell is accessed by read and refresh bitline 221 and then the sense amplifier amplifies the read-out signal and compensates the lost charge from the access and leakage back into the storage cell. After port 202 is on, the voltage held in storage cell is overwritten by write bitline 222 and then the sense amplifier compensates the lost charge from the access and leakage back into the storage cell. If the write transaction is writing to certain bitlines, the unwritten bitline 222 and write sense amplifier only compensates the lost charge back into the respective storage cell. Note that PMOS is used in the preferred cell embodiment of the present invention. In modern semiconductor process, PMOS is implanted in nwell which is implanted in substrate; in contrast, NMOS is directly grow in the substrate. The memory cells made of NMOS is subject to the strong switching noise injected from any peripheral circuitry and yield more weak bits or failing bits. Therefore, PMOS provides better noise immunity. In the sub-micron domain, gate oxide becomes thinner than 30 Ang and is subjected to the quantum tunneling effect; in other words, gate leakage current becomes significant and dominant. Carriers in PMOS is a hole which is heavier than one in NMOS as an electron. Therefore, gate leakage of PMOS is one tenth of NMOS. Note that DRAM cell is sensitive to all kinds of leakage currents. It is preferred to use PMOS instead of NMOS in terms of leakage and noise.

FIG. 2b shows a schematic diagram of dual-port DRAM cell 200B that may be used in memory data lodge illustrated as an example in the preferred embodiment of the present invention. The dual-port DRAM cell 200B has two ports 241 and 242. Port 241 is controlled by read and write wordline 241 and port 242 is controlled by write wordline 242. The dual-port DRAM cell 200B includes a storage node 251, which may be a PMOS capacitor. The active channel of PMOS capacitor 251 is the place to store data charge. In order to keep channel active in data “0” scenario, external voltage VCAPEN is hold as a negative voltage generated by charge pump or from an external source. Port 241 is turned on only when either read or write activity takes place for the cell and port 242 is turned on only when write activity takes place for the cell. After port 241 is on in case of a read scenario, the voltage held in storage cell is accessed by read and write bitline 261 and then the sense amplifier amplifies the read-out signal and compensates the lost charge from the access and leakage back into storage cell 251. After port 241 is on in case of write, the voltage held in storage cell is overwritten by write bitline 261 and then the sense amplifier compensates the lost charge from access and leakage back into storage cell. After port 242 is on, the voltage held in storage cell 251 is overwritten by write bitline 262 and then the sense amplifier compensates the lost charge from access and leakage back into storage cell 251. If the write transaction is writing to certain bitlines, the unwritten bitline 242 and write sense amplifier only compensates the lost charge back into the respective storage cell 251.

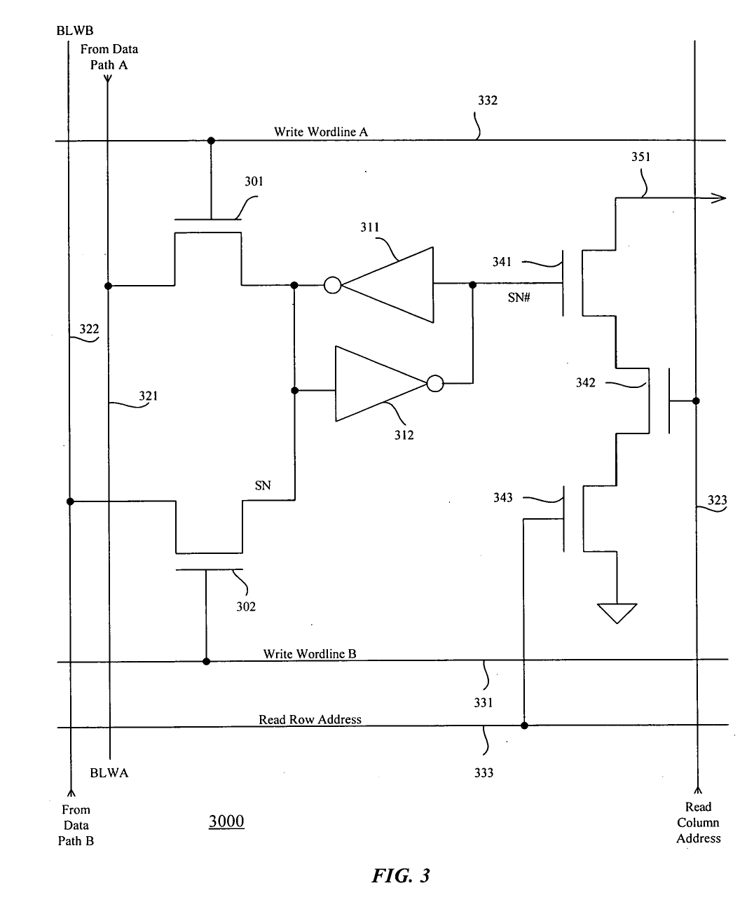

FIG. 3 shows a schematic diagram of a LUT entry cell 3000 in accordance with the preferred embodiment of the invention. The LUT entry cell 3000 includes two write ports 301 and 302, a bi-stable inverter pairs 311 and 312, an entry switch 341, a row switch 342 and a column switch 343. Write ports 301 and 302 are connected to bitline 321 and 322 respectively. Only write operation are performed thru port 301 and 302. The write data is settled down on bitline 321 and 322 before port 301 and 302 are turned on. Port 301 and 302 can not be turned on simultaneously other than in an overlapping mode. The bi-stable inverter pairs 311 and 312 are used to store the entry bit. Both ends are used to store complementary data of the entry bit. Each entry bit represents one word address entry in a dual-port memory bank. For example, 32 rows and 512 columns dual-port memory banks means 1024 words entries, each word being 16-bits in length. By default, sn is set as 1 and sn# is set as 0. So the entry switch 341 is turned off and column match bus 351 is kept unasserted by this entry cell.

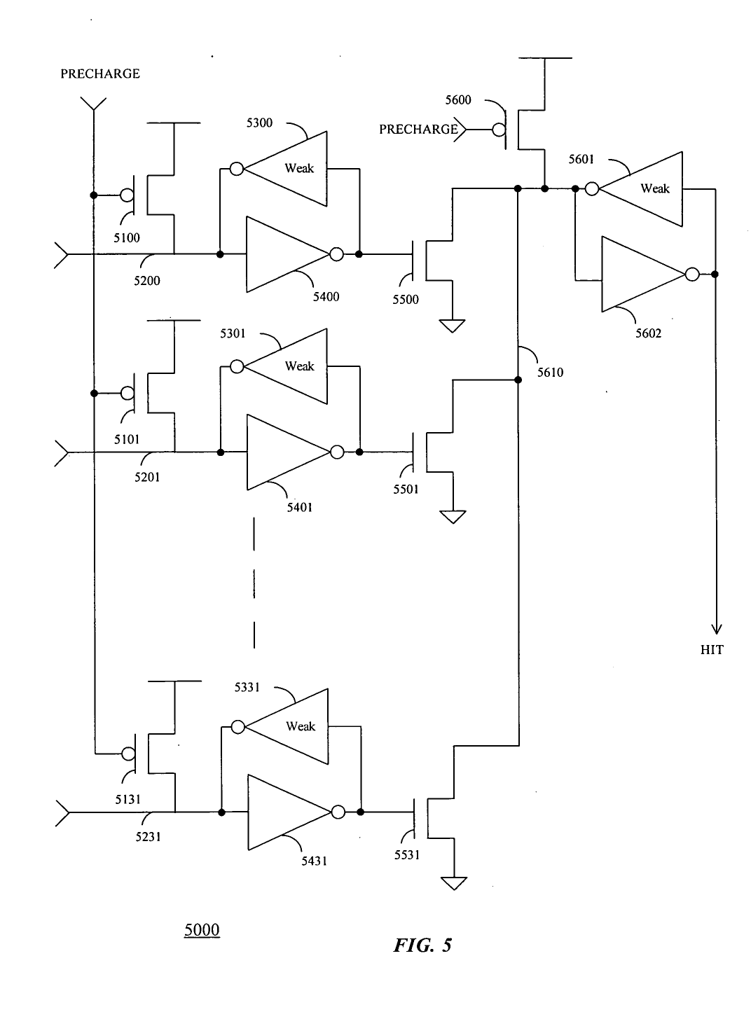

Column match bus 351 is precharged to logic 1 by default. If a recent access to this cell 3000 takes place, either port 301 (external read operations) or port 302 (external write operations) is turned on and the preset value of 0 from bitline 321 or 322 is written into cell so that sn is 0 and sn# is 1 thereafter. The entry switch 341 is turned on from this point. When next read access hits this cell, that is, row address bit 323 is set as 1 and column address bit 343 is set as 1, column match bus 351 is pull down to ground. Therefore a hit in one address entry is generated and column match bus 351 conveys this hit signal to final hit logic unit as illustrated in FIG. 5.

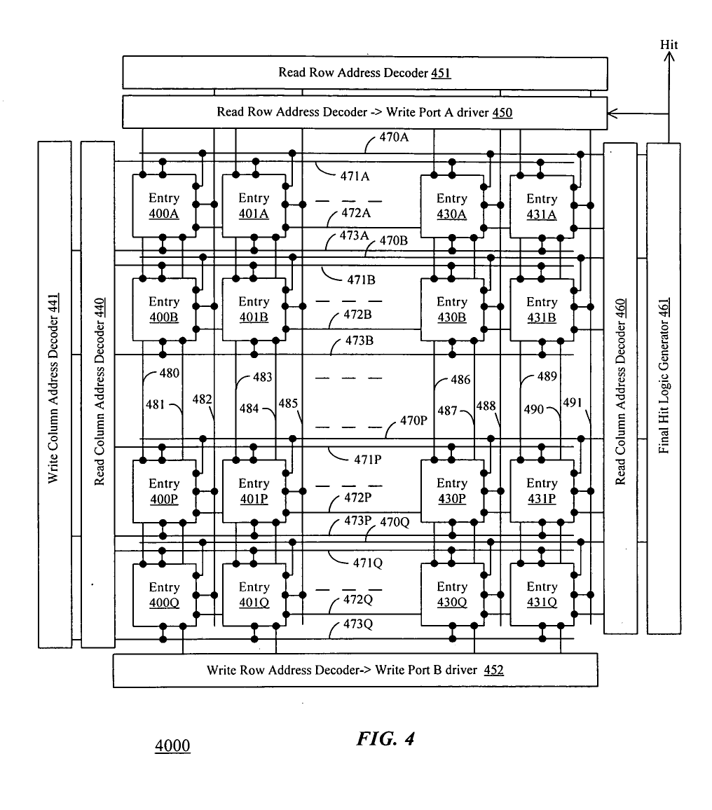

FIG. 4 shows a block diagram of a LUT logic system 4000 with LUT entry cells that may be used in the embodiments of the present invention. The LUT logic systems 4000 includes entry cell array 400A-431Q, read and write column address decoder 440 and 441, read and write row address decoder 450, 451, 452, read column address decoder 460 and final hit logic generator 461.

Read and write row address decoder 450 and 452 are used to locate operating row in the entry cell array 400A-431Q. For example, row 480 is set for accessing entry 400A-Q. Row 480, 483, 486, 489, etc. are operated by read row address decoder 450. Row 481, 484, 487, 490 etc. are operated by write row address decoder 452. Row 482, 485, 488, 491 etc. are operated by read row address decoder 451. Column 471A-Q is operated by read column address decoder 440. Column 473A-Q is operated by write column address decoder 441. Column 472A-Q is operated by read column address decoder 460. Column match bus 470A-Q is connected to final hit logic generator 461. Each column is attached to a column of entry cells. For example, column 470A is attached to entry 400-431A. Each row is attached to a row of entry cells. For example, row 481 is attached to entry 400A-Q.

During a clock cycle, only one of the rows is turned on and the rest is kept unchanged; and only one of columns is turned on and the rest is kept unchanged. Read row address decoder 450 and read column address decoder 440 are used to locate a specific cell entry and set “accessed tag” according to a read access to refresh-jammed bank thru write port A of this cell. Write row address decoder 452 and write column address decoder 441 are used to locate a specific cell entry and set “accessed tag” according to a write access to refresh-jammed bank thru write port B of this cell. Read row address decoder 451 and read column address decoder 460 are used to locate a specific cell entry and generate logic of the corresponding column match bus according to a current read access to refresh-jammed bank. Final hit logic generator 461 synthesizes all information of column match buses 470A-Q and determines whether there is a read hit. The detailed schematic of final hit logic generator 461 is explained in FIG. 5.

FIG. 5 shows a schematic diagram of hit logic generator 5000 that may be implemented in the LUT logic in accordance to embodiments of the present invention. Hit logic generator 5000 includes 32 groups of circuit 5100-5131, 5300-5331, 5400-5431 and 5500-5531 and pre-charge PMOS 5600 and an inverter 5602 and a holder 5601. PMOS 5100-5131 are connected to 32 column match buses 5200-5231 and pre-charge 32 column match buses voltage level to logic “1” in precharge phase. In the evaluation phase, if it is a read miss, all buses 5200-5231 are kept as logic “1” and thus all of switches 5500-5531 are turned off. Node 5610 is kept as its precharged level—logic “1” by PMOS 5600 during the precharge phase. Weak inverters 5300-5400 are designed to hold value of buses 5200-5231 from noise interference. Weak inverter 5601 is designed to hold value of 5610 from noise interference. Therefore, hit is kept as low. If it is a read hit, one of buses 5200-5231 is set to logic “0” in the evaluation phase, and the rest are kept unchanged. Thus, one of NMOS switchs 5500-5531 is turned on and node 5610 is pulled down. Consequently, hit is generated and set as “1” during this evaluation phase. A pulse of precharge signal is divided into two phases. When a pulse is low, all PMOS 5100-5131 and 5600 are turned on. It is defined as a precharge phase. When a pulse is high, all PMOS 5100-5131 and 5600 are turned off. This phase is defined as the evaluation phase.

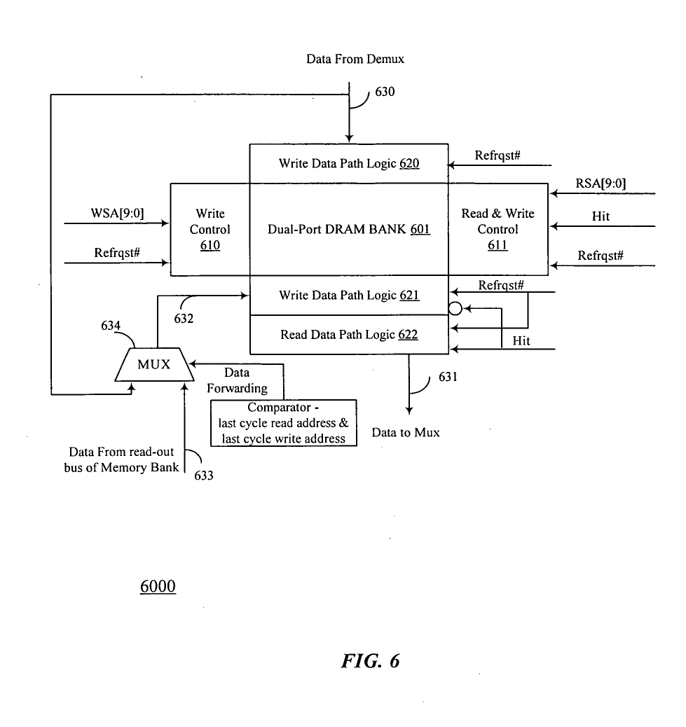

FIG. 6 shows a block diagram of dual-port memory data lodge 6000 system that may be used in accordance with the embodiments of the present invention. Data Lodge 6000 includes a dual-port memory bank 601, write control 610, read and write control 611, write data path logic 620, write data path logic 621, read data path logic 622 and MUX 634. Write control 610 receives the latched write address from write address latches 181 and control signals. Write control 610 is enabled by Refrqst # low and associated with the write port of dual-port memory bank 601. Write data bus of the dual-port memory bank 601 is attached with write data path logic 620. Write data path logic 621 and read data path logic 622 shares a read data bus which is attached with the read port of dual-port memory bank 601. Note that read data path logic 622 is enabled when a read hit occurs; otherwise, write data path logic 621 is activated. This control mechanism assures no bus conflicts between write data path logic 621 and read data path logic 622. Input data for write data path logic 621 is output from MUX 634.

In general, write data path logic 621 accepts the data read out from read memory bank and this data will be ready until the next cycle of read command since the access process has to be done in accessed memory bank. However, data lodge 6000 with write-through policy directs input data to write data path 620 without delay. It reverses the timing relationship between write data path logic 620 and 621 by half cycle. If read and write address in one cycle is different, this reverse does not cause any problem. If the read and write address in one cycle is the same, this reverse may cause data coherency problem. Mux 634 is placed to forward the correct write data into write data logic 621 if this scenario occurs. Read and write control 611 correlated with data path logic 621 and 622 is further controlled by hit and refrqst#. If a read hit takes place, read control part of 611 is activated and read operation is performed to create idle cycle, provide the output data to the external data bus. Otherwise, the write control part of 611 is activated and write operation is performed to transfer the data read from the refresh-jammed bank into dual-port memory bank 601. Read and write part of control 611 is exclusive upon hit. Write and read data path logic 621 and 622 are exclusive operations. Data lodge 6000 is activated only if refreqst# is low. If there is no refresh stall, the data lodge 6000 is inactive.

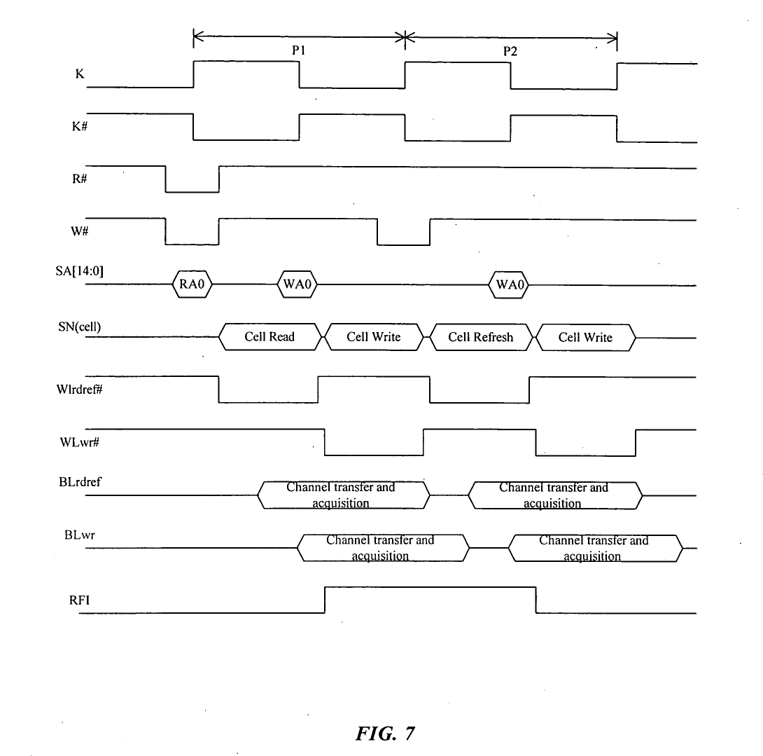

FIG. 7 shows a waveform diagram illustrating the overlapping read or refresh and write operations executed sequentially in accordance with one embodiment of the present invention. In consecutive two clock cycles, one read, one refresh and two write operations to the same memory cell is demonstrated.

During clock cycle P1, R# and W# is sampled by the rising edge of K and the read address RA0 is latched by the rising edge of clock signal K and the write address WA0 is latched by the rising edge of clock signal K#. Read command and address are decoded into access to a particular cell (SN) and wordline to control read and refresh port of this cell is turned on and read transaction is proceeded; then, data from cell is transferred into read and refresh bitline. Wordline to read and refresh port is then turned off after transferred is done. Following the read port off, wordline to control the write port is turned on to perform the write operation from write bitline and turned off after data transfer into cell is done. In this sequence, the cell capability is fully utilized and the maximal bandwidth of cell access can be achieved.

During clock cycle P2, one write operation in the same cell is detected but no read operation. Yet, a refresh invoke command is triggered in this cycle and hence the refresh operation is performed in this cell. A similar access pattern is repeated in P2 cycle except that the data on the refresh bitline is not transferred to the external data bus.

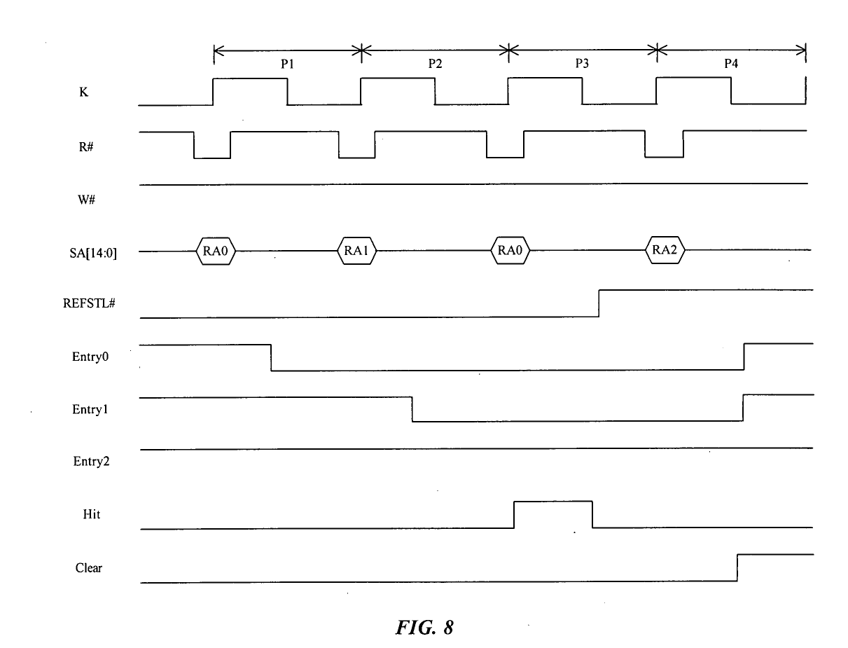

FIG. 8 shows a waveform diagram illustrating the timing of hit generation in four consecutive read operations in accordance with the an embodiment of the present invention. Here, four consecutive read operations in the same bank are carried out. Read address sequence is RA0, RA1, RA0 and RA2, which includes a repeat read to a same address RA0 and to three other different read locations. The refresh stall is set low before the cycle P1 and thus the LUT logic is active to register the accessed address and generate hit logic. Entry0 for RA0 is initially high. During the P1 clock cycle, entry0 for RA0 is set low since a recent access is performed and no hit is carried out. During the P2 clock cycle, entryl for RA1 is set low. During the P3 clock cycle, a hit is generated by ready-setting “0” of entry0 and thus, refresh stall signal is unlocked after the falling edge of clock K. During the P4 clock cycle, access to RA2 is bypassed since the LUT logic is inactive now and a clear signal in LUT logic is generated to reset all the entries.

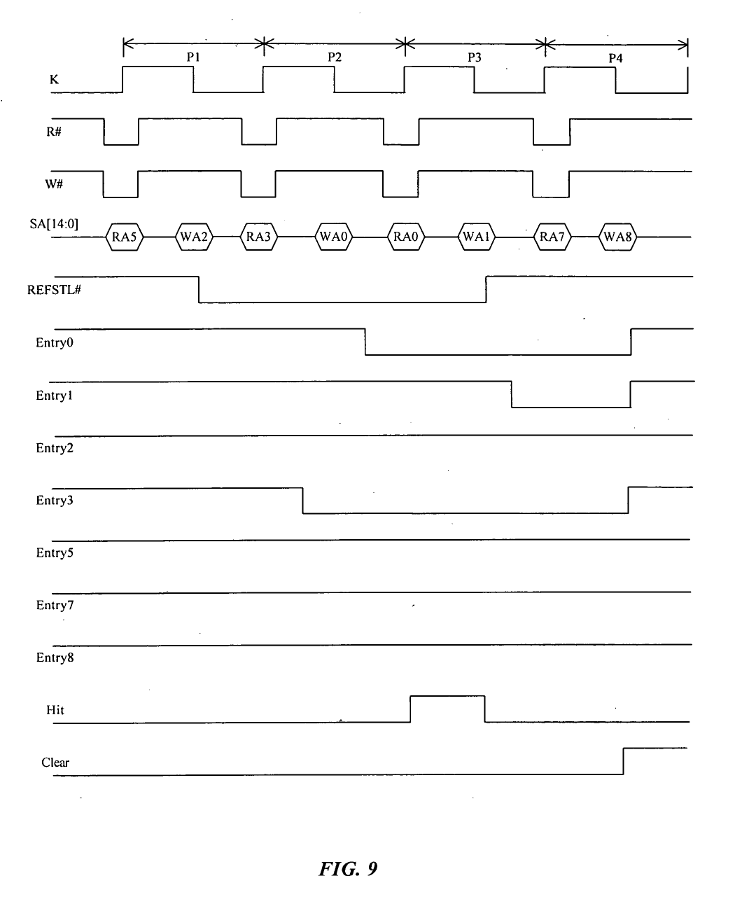

FIG. 9 shows a waveform diagram illustrating the timing of the hit generation in four consecutive read and write operations in accordance with the preferred embodiment of the present invention. Here, four consecutive read and write operations in the same bank are carried out. Read and write address sequence is RA5, WA2, RA3, WA0, RA0, WA1, RA7 and WA8. The refresh stall is set high before the P1 cycle and thus the LUT logic is inactive at this point. All entries are initially high.

During the P1 clock cycle, read operation to RA5 and write operation to WA2 are performed but entry5 is not affected since the LUT logic is inactive. At the falling edge of K, refresh stall (REFSTL#) is generated and set low and then the LUT logic is activated to response in the next cycle. During the P2 clock cycle, entry3 and entry0 are set low since the read operation to RA3 and write operation to WA0 are performed and the LUT logic is active in this period. During the P3 clock cycle, a read hit is generated since a read operation to RA0 is performed and entry0 is previously set from recent write access of this address. Entry1 is set low since write operation to WA1 is carried out and refresh stall is still on. At the falling edge of clock K, refresh-jammed bank clears the refresh stall since this bank successfully got refreshed in hit cycle. During the P4 clock cycle, access to RA7 and WA8 is bypassed since the LUT logic is inactive now and a clear signal in LUT logic is generated to reset all the entries thereafter.

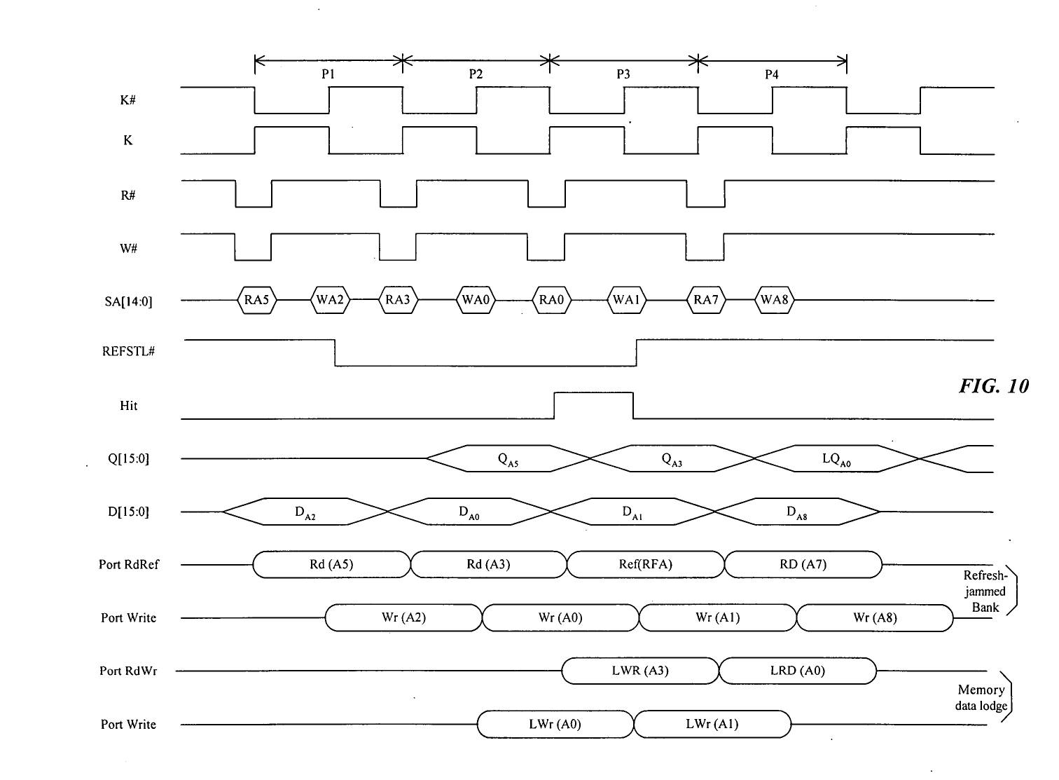

FIG. 10 shows a waveform diagram illustrating the timing of four consecutive read and write operations in accordance with the preferred embodiment of the present invention. Here, four consecutive read and write operations are performed and data transfer in and out is demonstrated. A0-A5 (M) are addresses in the bank M and A7-A8 (N) are addresses in the bank N. During the P1 cycle, a read to A5 and a write to A2 in bank M are performed without LUT logic participation. Bank M issues a refresh stall request to LUT logic since refresh command in Bank M is not performed by continuous and lasting read activities. The input data received from external source is directly written into bank M according to address A2 and the read-out data from bank M is sent directly to external data bus Q[15:0]. During the P2 cycle, the LUT logic starts to register any incoming read and write access to bank M in order to produce an idle cycle in a certain period. The dual-port memory lodge is started to collect the data and update the content associated with the recent accessed address. Note that data read out from A3 is written into the memory data lodge in the next cycle and data written into A0 is directly written into the memory data lodge without delay. Data coherency is assured by the data forwarding technique. Since read to A3 is a read miss, the data transfer is performed in the same manner of P1 cycle and thus the refresh demand is not fulfilled in this cycle in bank M. During the P3 cycle, a read hit is caught by registered A0 read access and the memory data lodge ships out the stored data for the external data bus Q[15:0]; and bank M gets a chance to execute its refresh operations without impact on external access. A refresh stall request is removed after this successful refresh. The write transaction to bank M in address 1 is still performed because of the advantages of dual-port cell. During the P4 cycle, a read access to A7 and a write access to A8 in bank N are performed and the LUT logic and data lodge is disabled and has no impact on the data transfer path. The data flow is performed in the same manner as the P1 cycle. During the P5 cycle, neither the read nor the write transaction is carried out. The memory device is in idle and data transfer does not take place in this cycle.

While the present invention has been described with reference to certain preferred embodiments, it is to be understood that the present invention is not to be limited to such specific embodiments. Rather, it is the inventor's contention that the invention be understood and construed in its broadest meaning as reflected by the following claims. Thus, these claims are to be understood as incorporating and not only the preferred embodiment described herein but all those other and further alterations and modifications as would be apparent to those of ordinary skilled in the art.

1. A memory device, comprising:
an address latch for receiving one or more data addresses;
an input buffer for receiving data to be written to said memory device;
access logic for receiving one or more request signals indicating a read operation or a write operation to said memory device;
one or more memory banks, each of said memory banks having a plurality of dual-port memory cells, wherein each of said memory cells having a first port designated for write operations only and a second port designated for read and refresh operations only, and said memory cells requiring refresh operations on a periodic basis; and
a control circuit for operating said memory banks in response to said request signals and for coordinating the refreshing of said memory cells without delaying any read operations or write operations.

2. A memory device as recited in claim 1 further comprising a dedicated write bus coupling said input buffer with said memory cells and a dedicated read bus coupling said input buffer with said memory cells.

3. A memory device as recited in claim 1 further comprising look-up table logic and a memory data lodge coupling with said input buffer, said address latch, said access logic, and said memory banks, wherein said look-up table logic and said memory data lodge operating to allow refreshing of the memory banks without delaying the read operations or the write operations.

4. A memory device as recited in claim 3 wherein, in a write operation, upon activation of a refresh-stall signal, data is written to the designated memory cell and, if a corresponding entry is not set in said look-up table logic, to said memory data lodge.

5. A memory device as recited in claim 3 wherein in a read operation, data is read from the designated memory cell, and, upon the activation of a refresh-stall signal, written in said memory data lodge if a corresponding entry is not set in said look-up table logic.

6. A memory device as recited in claim 4 wherein in a read operation, data is read from the designated memory cell, and, upon the activation of a refresh-stall signal, written in said memory data lodge if a corresponding entry is not set in said look-up table logic.

7. A memory device as recited claim 5 wherein, upon the activation of a refresh-stall signal and where a read operation and a write operation is to the same memory cell during the same clock cycle, in said write operation, the data is written to the designated location in said memory data lodge and to the memory cell of the corresponding memory bank, and, in said read operation, the read data is not written to said memory data lodge.

8. A memory device as recited claim 6 wherein, upon the activation of a refresh-stall signal and where a read operation and a write operation is to the same memory cell during the same clock cycle, in said write operation, the data is written to the designated location in said memory data lodge and to the memory cell of the corresponding memory bank, and, in said read operation, the read data is not written to said memory data lodge.

9. A memory device as recited in claim 1 further comprising a global refresh circuit for directing the refresh operations of said memory banks.

10. A memory device as recited in claim 1 wherein each of the memory banks has a local refresh circuit for monitoring and issuing a refresh stall signal.

11. A memory device as recited in claim 9 wherein each of said memory banks having a local refresh circuit for monitoring and issuing a refresh stall signal.

12. A memory device as recited in claim 1 wherein each of said memory cell is a 3-transistor cell.

13. A memory device as recited in claim 3 wherein said look-up table logic and said memory data lodge clears a refresh-stall condition with a memory bank before a refresh operation is needed for said memory data lodge.

14. A memory device as recited in claim 1 wherein the read operation and the write operation overlaps thereby providing double bandwidth throughput.

15. A method for operating a memory device having a plurality of memory banks of memory cells, said memory cells requiring a refresh operation on a periodic basis, comprising the steps of:
receiving a request signal for accessing a particular memory cell, said request signal indicating a write operation to said particular memory cell or a read operation from said particular memory cell; and
if said request signal indicating a write operation,
writing to said particular memory cell, and
if a refresh-stall signal is active, writing to the corresponding memory cell in a memory data lodge and marking a corresponding entry in a look-up table;
else if said request signal indicating a read operation,
if the refresh-stall signal is active,
if an entry in a look-up table corresponding to the address of said particular memory cell is set, read from a memory cell (corresponding to said particular memory cell) from said memory data lodge, outputting said read data, refreshing said corresponding memory bank, clearing said refresh-stall signal;
else reading data from said particular memory cell, writing said read data to a memory data lodge and marking a corresponding entry in a look-up table, and outputting said read data;
else
reading data from said particular memory cell and outputting said read data.

16. A method as recited in claim 15 wherein in a read operation, if said refresh-stall signal is active and if there is a read operation and a write operation to the same memory cell, in said read operation, the data to be written to said memory data lodge is discarded.

17. A method as recited in claim 15 wherein said refresh-stall signal is generated when the respective memory cell to be refreshed is in a read operation and not available for a refresh operation.

18. A method as recited in claim 15 wherein said refresh-stall signal is cleared before a refresh operation is needed for said memory data lodge.

19. A memory cell, comprising:
a first transistor having its gate connected to a read/refresh wordline, its first node connected to a read/refresh bitline, and its second node connected to a first node of a storage capacitor; and
a second transistor having its gate connected to a write wordline, its first node connected to a write bitline, and its second node connected to a second node of said storage capacitor.

20. A memory cell as recited in claim 19 wherein said first transistor and said second transistor are MOSFET transistors.

21. A memory cell as recited in claim 19 wherein said storage capacitor is a MOSFET capacitor with its gate connected to a designated voltage.

22. A memory cell as recited in claim 21 wherein said MOSFET is a PMOS and said designated voltage is a negative voltage.

23. A memory cell as recited in claim 21 wherein said MOSFET is a NMOS and said designated voltage is a positive voltage.
